(19) United States
(12) Patent Application Publication
(10) Pub. No.: US 2025/0183874 A1
(43) Pub. Date: Jun. 5, 2025

(54) Elastic Wave Device and Module

(71) Applicant: Sanan Japan Technology Corporation, Tokyo (JP)

(72) Inventors: Jingri Lian, Tokyo (JP); Shinichi SHIOI, Tokyo (JP)

(21) Appl. No.: 18/963,430

(22) Filed: Nov. 27, 2024

(30) Foreign Application Priority Data
Nov. 30, 2023 (JP) 2023-203492

(51) Int. Cl. H03H 9/25; H03H 9/02; H03H 9/145; H03H 9/64

(52) U.S. Cl. CPC H03H 9/25; H03H 9/02992; H03H 9/14541; H03H 9/6483

(57) ABSTRACT

This disclosure relates to an elastic wave device and module. The elastic wave device includes a plurality of series resonators and a plurality of parallel resonators, as well as a bandpass filter that allows signals within a predetermined frequency band to pass through. The plurality of series resonators includes a first series resonator with a first anti-resonant frequency and a second anti-resonant frequency. The first anti-resonant frequency is located near the lowest frequency within the predetermined frequency band, and the second anti-resonant frequency is located above the highest frequency within the predetermined frequency band. This elastic wave device and module address the issue of insufficient steepness between the passband and stopband, thereby enhancing the steepness between the passband and stopband in the elastic wave device.

### CROSS-REFERENCE TO RELATED APPLICATION

The present disclosure claims priority to Japanese Patent Application No. JP2023-203492 filed Nov. 30, 2023, the contents of which are herein incorporated by reference in its entirety.

### FIELD

This application relates to the field of semiconductor technology, particularly to an elastic wave device and a module.

### BACKGROUND

With advancements in technology, devices such as smartphones, exemplified by mobile communication terminals, are becoming increasingly miniaturized and lightweight. Elastic wave devices with miniaturization potential are employed in these mobile communication terminals. Additionally, as communication systems capable of simultaneous signal transmission and reception within mobile communication systems rapidly increase, the demand for duplexers is also growing significantly.

With changes in mobile communication systems, the specifications required for elastic wave devices are becoming more stringent.

In other words, there is a demand for characteristics superior to those of previous devices.

A higher level of steepness between the passband and the stopband is required.

Patent Document 1 (Japanese Patent Application Laid-Open No. 2014-160888) discloses a technique for enhancing the steepness of the pass characteristics on the high-frequency side of the passband. However, the elastic wave device described in Patent Document 1 has insufficient steepness between the passband and the stopband.

### SUMMARY

The present disclosure has been made to overcome the aforementioned issues. Its objective is to provide an elastic wave device with improved steepness between the passband and the stopband and a module incorporating such a device.

In a first aspect, the elastic wave device according to this disclosure comprises a plurality of series resonators and a plurality of parallel resonators and includes a bandpass filter that allows signals within a predetermined frequency band to pass through.

The plurality of series resonators includes a first series resonator with a first anti-resonant frequency and a second anti-resonant frequency;

The first anti-resonant frequency is located near the lowest frequency within the predetermined frequency band;

The second anti-resonant frequency is located above the highest frequency within the predetermined frequency band.

According to this disclosure, the attenuation characteristics of the elastic wave device can be improved on both the low-frequency side and the high-frequency side of the passband.

The details of one or more embodiments of this application are presented in the following drawings and description, making other features, purposes, and advantages of this application more clear.

### BRIEF DESCRIPTION OF THE DRAWINGS

The accompanying drawings are intended to provide a further understanding of the present application, constitute part of this application, and illustrate exemplary embodiments of this application. The description and drawings do not limit the scope of the application.

FIG. 1 is a longitudinal sectional view of the elastic wave device in Embodiment 1.

FIG. 2 is an example illustration of the elastic wave element (resonator) in the elastic wave device of Embodiment 1.

FIG. 3 is an example illustration of the elastic wave device in Embodiment 1.

FIG. 4 is a graph of the anti-resonance characteristics of the series resonator S1-1 of the receiving filter 30 in the elastic wave device 20 in Embodiment 1.

FIG. 5 is a graph of the pass characteristics of the receiving filter 30 in the elastic wave device 20 in Embodiment 1.

FIG. 6 is a pitch modulation diagram of the SAW resonator with an IDT electrode in the series resonator S1-1 of the receiving filter 30 in the elastic wave device 20 in Embodiment 1.

FIG. 7 is a longitudinal sectional view of the module in which the elastic wave device in Embodiment 1 is applied.

In the drawings: 20. Elastic wave device; 23. Wiring substrate; 24. External connection terminal; 25. Device chip; 26. Electrode pad; 27. Bump; 28. Sealing section; 30. Receiving filter; 52. Elastic wave element; 52a. IDT electrode; 52b. Reflector; 52c. Comb electrode; 52d. Electrode finger; 52e. Bus bar; IN. Input pad; OUT. Output pad; GND. Ground pad; 100. Module; 130. Wiring substrate; 131. External connection terminal; IC. Integrated circuit component; 111. Inductor; 117. Sealing section.

### DETAILED DESCRIPTION

To better understand the objectives, technical solutions, and advantages of this application, the following description and illustrations are provided based on the drawings and embodiments. The embodiments are described with reference to the drawings, where the same or corresponding parts are marked with the same reference numerals. Repeated explanations are simplified or omitted as appropriate.

### Embodiment 1

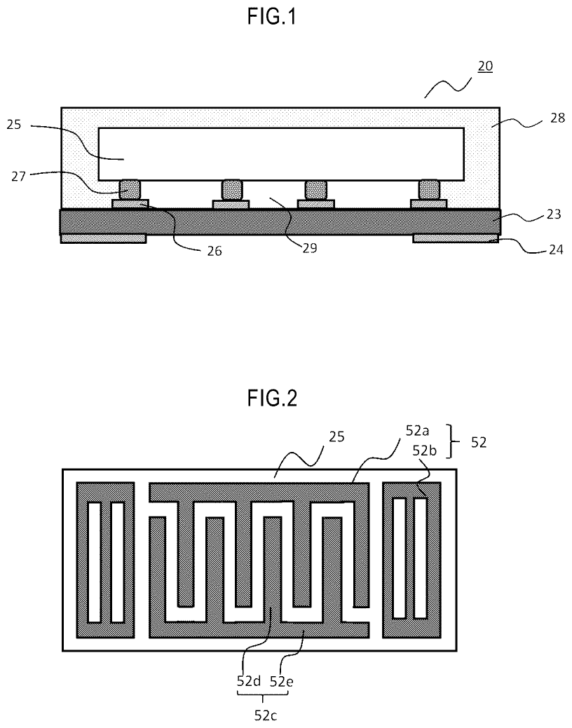

FIG. 1 shows a longitudinal sectional view of the elastic wave device in Embodiment 1.

As shown in FIG. 1, the elastic wave device 20 includes a wiring substrate 23, external connection terminals 24, a device chip 25, electrode pads 26, bumps 27, and a sealing section 28.

The wiring substrate 23, for example, is a multilayer substrate made of resin. For instance, the wiring substrate 23 may be a low-temperature co-fired ceramic (LTCC) multilayer substrate comprising multiple dielectric layers.

Several external connection terminals 24 are formed on the lower surface of the wiring substrate 23.

Electrode pads 26 are formed on the main surface of the wiring substrate 23. The electrode pads 26, for example, are made of copper or a copper alloy and have a thickness ranging from 10 μm to 20 μm.

Bumps 27 are formed on the upper surface of each electrode pad 26. For instance, the bumps 27 are gold bumps with a height between 10 μm and 50 μm.

A gap 29 is formed between the wiring substrate 23 and the device chip 25.

The device chip 25 is mounted on the wiring substrate 23 via flip-chip bonding through the bumps 27. The device chip 25 is electrically connected to the electrode pads 26 via multiple bumps 27.

The device chip 25, for example, is a surface acoustic wave (SAW) device chip, containing a piezoelectric substrate formed of a piezoelectric material. The piezoelectric substrate may be made from piezoelectric single-crystal materials such as lithium tantalate, lithium niobate, or quartz. The piezoelectric substrate has a thickness of 100 μm to 300 μm, while in other examples, it may be made from piezoelectric ceramic.

In other embodiments, the device chip 25 is formed by combining a piezoelectric substrate and a support substrate. The support substrate can be made from materials such as sapphire, silicon, aluminum oxide, spinel, quartz, or glass. In this case, the piezoelectric substrate has a thickness of 0.3 μm to 5 μm.

Elastic wave elements 52 are formed on the piezoelectric substrate. For example, multiple elastic wave elements 52 are formed on the main surface of the device chip 25, constituting a transmission filter or receiving filter.

In other embodiments, both transmission and receiving filters are formed as a duplexer on the main surface of the device chip 25.

The transmission filter is a ladder filter composed of multiple series and parallel resonators for transmitting electrical signals within a desired frequency band.

The receiving filter is also a ladder filter for receiving electrical signals within a desired frequency band.

The sealing section 28 is formed to cover the device chip 25. The sealing section 28 may be made from an insulating material such as synthetic resin or a metal.

When the sealing section 28 is made from synthetic resin, suitable materials include epoxy resin or polyimide. Preferably, the sealing section 28 is formed using an epoxy resin through a low-temperature curing process. A gap 29 is formed in the area of the wiring substrate 23 opposite to the device chip 25.

Next, with reference to FIG. 2, an example of the elastic wave element 52 formed on the device chip 25 is described. FIG. 2 is an example illustration of the elastic wave element (resonator) in the elastic wave device of Embodiment 1.

As shown in FIG. 2, an interdigital transducer (IDT) electrode 52a and a pair of reflectors 52b are formed on the main surface of the device chip 25. The IDT electrode 52a and the pair of reflectors 52b are configured to excite elastic waves (mainly SH waves).

For example, the IDT electrode 52a and the pair of reflectors 52b are made from an alloy of aluminum and copper. Alternatively, suitable metals or alloys for the IDT electrode 52a and the pair of reflectors 52b include aluminum, molybdenum, iridium, tungsten, cobalt, nickel, ruthenium, chromium, strontium, titanium, palladium, and silver.

For Example, the IDT electrode 52a and the pair of reflectors 52b are made of a multilayer metal film laminate. The thickness of the IDT electrode 52a and the pair of reflectors 52b is, for example, between 150 nm and 450 nm.

The IDT electrode 52a includes a pair of comb electrodes 52c, which face each other. Each comb electrode 52c consists of multiple electrode fingers 52d and a bus bar 52e.

The multiple electrode fingers 52d are arranged in alignment along the long-side direction.

The bus bar 52e connects the multiple electrode fingers 52d.

One of the reflectors 52b is adjacent to one side of the IDT electrode 52a, while the other reflector 52b is adjacent to the opposite side of the IDT electrode 52a.

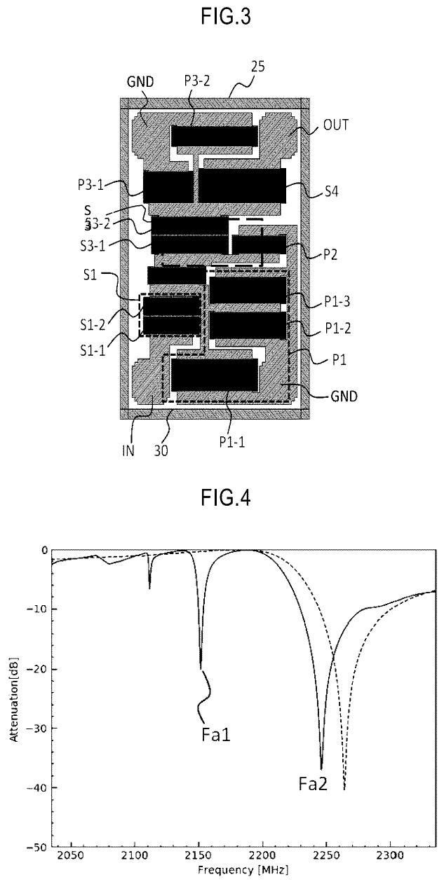

Next, an example of the bandpass filter formed on the device chip 25 is described with reference to FIG. 3. FIG. 3 is an example illustration of the elastic wave device in Embodiment 1.

As shown in FIG. 3, the bandpass filter formed on the device chip 25 is the receiving filter 30. The receiving filter 30 includes an input pad IN, an output pad OUT, and a ground pad GND.

Additionally, the receiving filter 30 comprises series resonators S1-1, S1-2, S2, S3-1, S3-2, and S4, as well as parallel resonators P1-1, P1-2, P1-3, P2, P3-1, and P3-2. The receiving filter 30 is configured as a ladder filter.

The series resonator S1-1 is positioned closest to the input pad IN in the circuit and is the first resonator to which an electrical signal is applied. The series resonators S1-1 and S1-2 are formed by dividing the primary series resonator S1 of the ladder filter in series.

Similarly, series resonators S3-1 and S3-2 are formed by dividing the series resonator S3 in series.

The parallel resonators P1-1, P1-2, and P1-3 are formed by dividing the primary parallel resonator P1 in parallel. Similarly, the parallel resonators P3-1 and P3-2 are formed by dividing the parallel resonator P3 in parallel.

FIG. 4 is a graph of the anti-resonance characteristics of the series resonator S1-1 in the receiving filter 30 of the elastic wave device 20 in Embodiment 1. The anti-resonance characteristics of series resonator S1-1 are shown with a solid line.

As a reference example, the anti-resonance characteristics of a conventional series resonator are shown with a dashed line. The first anti-resonant frequency Fa1 of the series resonator S1-1 is 2150 MHz, and the second anti-resonant frequency Fa2 is 2245 MHz.

Additionally, as shown in FIG. 4, in the reference example, only one anti-resonance characteristic exists, corresponding to the second anti-resonant frequency Fa2, and no anti-resonance characteristic corresponds to the first anti-resonant frequency Fa1.

The series resonator S1-1, together with the series resonator S1-2, forms the primary series resonator S1 of the ladder filter. In other words, the series resonator S1-1 is a part of the series resonator S1 after being divided in series, as shown in FIG. 3, and it is the resonator that first receives the electrical signal applied from the input terminal IN.

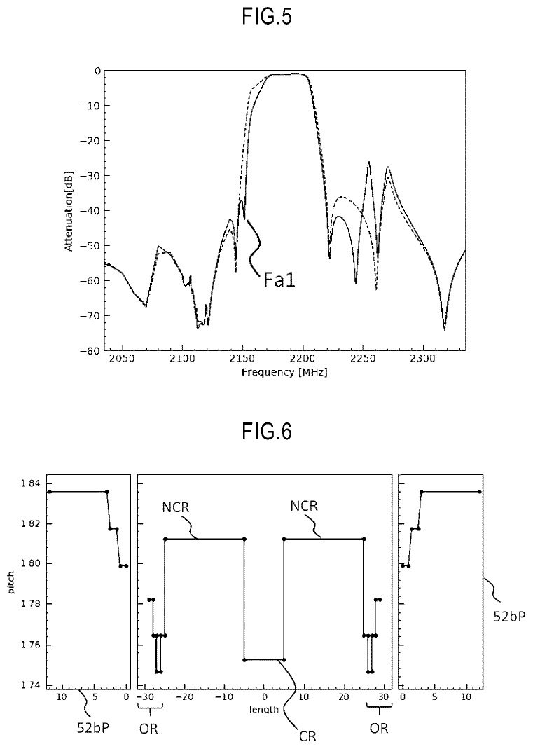

FIG. 5 shows the pass characteristics of the receiving filter 30 in the elastic wave device 20 in Embodiment 1. The solid line represents the pass characteristics of the receiving filter 30 in Embodiment 1, while the dashed line represents the pass characteristics of the reference example filter.

In FIG. 5, the first anti-resonant frequency Fa1 of the series resonator S1-1 is set near the low-frequency side of the passband of the receiving filter 30, which spans from 2170 MHz to 2200 MHz, within a range extending 25 MHz downward from the lowest frequency of the passband.

The passband of the receiving filter 30 in Embodiment 1 is set as the satellite communication reception band, with a range of 2170 MHz to 2200 MHz. The passband width is 30 MHz, and the relative bandwidth is 1.37%.

Here, the relative bandwidth refers to the value obtained by dividing the difference between the highest and lowest frequencies in the band by the center frequency of the band.

The anti-resonant frequency of the series resonator S1-1 is 2250 MHz, which is above the highest frequency of the passband of the receiving filter 30.

Setting the first anti-resonant frequency Fa1 of the series resonator S1-1 near the low-frequency side of the pass characteristics of the receiving filter 30 (between the lowest frequency of the passband and 25 MHz downward) allows the steepness on the low-frequency side of the passband characteristics to be enhanced due to the lower coupling coefficient of the first anti-resonant frequency Fa1.

Furthermore, setting the first anti-resonant frequency Fa1 of the series resonator S1-1 near the low-frequency side of the pass characteristics of the receiving filter 30 (between the lowest frequency of the passband and 25 MHz downward) improves temperature characteristics.

More specifically, the low-frequency side of the passband, typically referred to as the “left shoulder,” is generally defined by the resonance characteristics of the parallel resonator. However, the absolute value of the temperature coefficient of resonance frequency is greater for resonance characteristics than for anti-resonance characteristics, leading to poorer temperature characteristics.

By ensuring the absolute value of the temperature coefficient of the first anti-resonant frequency Fa1 of the series resonator S1-1 is smaller than its resonance frequency, and using this first anti-resonant frequency Fa1 to form the left shoulder (low-frequency side) of the passband, the temperature characteristics of the low-frequency side of the bandpass filter are improved.

Moreover, since the first anti-resonant frequency Fa1 contributes to forming the left shoulder (low-frequency side) of the passband, and the second anti-resonant frequency Fa2 contributes to the attenuation on the high-frequency side of the passband, the width of the passband is defined by the frequency difference between the first anti-resonant frequency Fa1 and the second anti-resonant frequency Fa2. Specifically, the passband width, where this series resonator S1-1 exhibits significant effects, is within 100 MHz.

FIG. 6 is a pitch modulation diagram for the SAW resonator with an IDT electrode in the series resonator S1-1 of the receiving filter 30 in the elastic wave device 20 in Embodiment 1.

The first pitch of the central region CR of the IDT electrode is 1.753 μm, with a duty ratio of 55%.

The second pitch of the two adjacent non-central regions NCR on either side of the central region CR is 1.813 μm, with a duty ratio of 50%.

The third pitch of the outer regions OR adjacent to the non-central regions NCR is not fixed. However, the third pitch of the outer regions OR is smaller than the second pitch of the non-central regions NCR.

The duty ratio of the outer regions OR is also 50%. Note that the duty ratio is defined as the proportion of the electrode finger width in one period.

In the reference example, the pitches of the central and non-central regions are the same.

By making the pitches of the central and non-central regions different, two anti-resonant frequencies are generated, specifically the second anti-resonant frequency Fa2 and the first anti-resonant frequency Fa1. Furthermore, the resonance frequency is located between the second and first anti-resonant frequencies Fa2 and Fa1.

Additionally, the pitch modulation 52bP of the reflectors is smaller than the pitch of the non-central region NCR in the region closest to the IDT electrode, while it is greater than the pitch of the non-central region NCR in the region farthest from the IDT electrode.

By configuring the series resonator S1-1 in this way, it not only retains its conventional function of ensuring the attenuation characteristics on the high-frequency side of the passband at the second anti-resonant frequency Fa2, but also allows the first anti-resonant frequency Fa1 to be set near the low-frequency side of the band (within 25 MHz below the passband's lowest frequency), thereby enhancing the steepness on the low-frequency side.

In summary, the description of Embodiment 1 provides an elastic wave device that enhances the steepness between the passband and the stopband.

### Embodiment 2

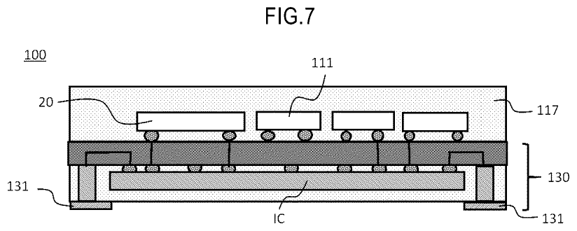

FIG. 7 is a longitudinal sectional view of a module incorporating the elastic wave device of Embodiment 1. It should be noted that the same reference numerals are used for components similar or corresponding to those in Embodiment 1, and their descriptions are omitted.

In FIG. 7, the module 100 includes a wiring substrate 130, multiple external connection terminals 131, an integrated circuit component (IC), the elastic wave device 20, an inductor 111, and a sealing section 117.

Multiple external connection terminals 131 are formed on the bottom of the wiring substrate 130. The terminals 131 are pre-mounted on the mainboard of a designated mobile communication terminal.

The integrated circuit component IC, including a switch circuit and a low-noise amplifier, is mounted within the wiring substrate 130.

The elastic wave device 20 is mounted on the main surface of the wiring substrate 130.

The inductor 111, for impedance matching, is also mounted on the main surface of the wiring substrate 130. For example, the inductor 111 may be an Integrated Passive Device (IPD).

The sealing section 117 encapsulates multiple electronic components, including the elastic wave device 20.

By the description of Embodiment 2, the module 100 is equipped with the elastic wave device 20. Therefore, a module that enhances the steepness between the passband and stopband can be provided.

Although several aspects of at least one embodiment have been described, those skilled in the art will readily conceive of various changes, modifications, and improvements. Such changes, modifications, and improvements are intended to be part of this disclosure and are within the scope of this disclosure.

It should be understood that the embodiments of the methods and apparatus described herein are not limited to the structures and arrangements of components specified in the above descriptions or illustrated in the drawings. These methods and apparatus can be implemented in other embodiments and achieved or executed in various ways.

The specific embodiments are given as examples only and are not intended to be limiting.

The terms and expressions used in this disclosure are for explanatory purposes only and should not be construed as limiting. The words “including,” “having,” “containing,” and variations thereof are intended to encompass the items listed thereafter, as well as equivalents and additional items.

The term “or” should be understood to mean that the term used with “or” can refer to any one, multiple, or all of the items specified.

References to directions such as front, back, top, bottom, left, right, horizontal, vertical, inner, and outer are for convenience of explanation and do not limit any spatial orientation or position of the components in this disclosure. Therefore, the above descriptions and illustrations are for example purposes only.

The expressions and terms used in this invention are for illustration and should not be construed as limiting. The terms “including,” “equipped with,” “having,” “comprising,” and variations thereof imply inclusion of the items listed and their equivalents and additional items.

The term “embodiment” as used in this application means that a specific feature, structure, or characteristic described in connection with an embodiment may be included in at least one embodiment of this application. The phrase does not necessarily imply the same embodiment in all instances, nor does it preclude combinations with other embodiments unless stated otherwise. Those skilled in the art will understand or implicitly recognize that the embodiments described in this application can be combined with others when no conflict arises.

The embodiments described above are merely specific implementations of this application and provide relatively detailed descriptions. They should not be construed as limitations on the scope of patent protection. It should be noted that various modifications, adjustments, and improvements can be made by those skilled in the art without departing from the spirit of this application, all of which fall within the scope of protection of this application. Therefore, the scope of protection of this application should be determined by the appended claims.

What is claimed is:

1. An elastic wave device, comprising a plurality of series resonators and a plurality of parallel resonators, and a bandpass filter that allows signals within a predetermined frequency band to pass through;
The plurality of series resonators includes a first series resonator having a first anti-resonant frequency and a second anti-resonant frequency;
The first anti-resonant frequency is located near the lowest frequency of the predetermined frequency band;
The second anti-resonant frequency is located above the highest frequency of the predetermined frequency band.

2. The elastic wave device according to claim 1, wherein the first anti-resonant frequency is within a range of 25 MHz downward from the lowest frequency of the predetermined frequency band.

3. The elastic wave device according to claim 1, wherein the first series resonator is the resonator to which an electrical signal is applied first among the plurality of series resonators.

4. The elastic wave device according to claim 1, wherein the bandpass filter includes a receiving filter.

5. The elastic wave device according to claim 4, wherein the receiving filter further includes an input pad, an output pad, and a ground pad; wherein the first series resonator is closest to the input pad.

6. The elastic wave device according to claim 4, wherein the receiving filter is for the satellite communication receiving band, with a range of 2170 MHz to 2200 MHz.

7. The elastic wave device according to claim 1, wherein the bandpass filter is a ladder filter; the first series resonator is one of the series resonators constituting the ladder filter after being divided in series.

8. The elastic wave device according to claim 1, wherein the first series resonator is a surface acoustic wave resonator with an IDT electrode, the IDT electrode comprising: A central region with a first pitch, two non-central regions adjacent to the central region with a second pitch, and two outer regions adjacent to the non-central regions with a third pitch;
Wherein the first pitch is smaller than the second pitch, and the second pitch is greater than the third pitch.

9. The elastic wave device according to claim 8, wherein the IDT electrode comprises a pair of comb-shaped electrodes; the comb-shaped electrodes comprise multiple electrode fingers and bus bars; the electrode fingers are arranged in the long edge direction; the bus bars are connected to the multiple electrode fingers.

10. The elastic wave device according to claim 8, wherein the thickness of the IDT electrode and the reflector is 150 nm to 450 nm.

11. The elastic wave device according to claim 8, wherein the first series resonator includes a pair of reflectors adjacent to the IDT electrode, and the pitch of the reflectors is less than the second pitch in the region closest to the IDT electrode and greater than the second pitch in the region farthest from the IDT electrode.

12. The elastic wave device according to claim 11, wherein the material of the IDT electrode and the reflector is an aluminum-copper alloy.

13. The elastic wave device according to claim 11, wherein the IDT electrode and the reflector are made of a multilayer metal film stack.

14. The elastic wave device according to claim 8, wherein the duty ratio of the central region of the IDT electrode is greater than the duty ratio of the non-central region of the IDT electrode.

15. The elastic wave device according to claim 1, wherein the predetermined frequency band of the bandpass filter is less than 100 MHz.

16. The elastic wave device according to claim 1, wherein the difference between the highest and lowest frequencies within the predetermined frequency band, divided by the center frequency of the predetermined frequency band, is 0.5% or more and 4.0% or less.

17. The elastic wave device according to claim 1, wherein the width of the predetermined frequency band is formed within the frequency difference between the first anti-resonant frequency and the second anti-resonant frequency.

18. A module comprising the elastic wave devices as claimed in claim 1.

19. The module according to claim 18, characterized in that the module includes a wiring substrate, external connection terminals, an integrated circuit component, an elastic wave device, an inductor, and a sealing portion; the external connection terminals are formed on the bottom surface of the wiring substrate; the integrated circuit component is mounted inside the wiring substrate; the elastic wave device and the inductor are mounted on the main surface of the wiring substrate.

20. The module according to claim 18, characterized in that the integrated circuit component includes a switch circuit and a noise amplifier.
